(19) United States
(12) Patent Application Publication
(10) Pub. No.: US 2018/0013430 A1
(43) Pub. Date: Jan. 11, 2018

(54) OPTICAL KEYBOARD

(71) Applicant: Primax Electronics Ltd., Taipei (TW)

(72) Inventors: Chia-Yuan CHANG, Taipei (TW); Shao-Lun HSIAO, Taipei (TW)

(21) Appl. No.: 15/266,952

(22) Filed: Sep. 15, 2016

(30) Foreign Application Priority Data
Jul. 11, 2016 (TW) 105121758

(51) Int. Cl. H03K 17/96; H03K 17/969; G06F 3/02

(52) U.S. Cl. CPC H03K 17/9629; G06F 3/021; H03K 17/969

(57) ABSTRACT

An optical keyboard includes an upper cover plate, a bottom plate, a circuit board and plural optical keys. The circuit board is arranged between the upper cover plate and the bottom plate. The circuit board is connected with the upper cover plate that is disposed on the circuit board. The plural keys are penetrated through corresponding openings of the upper cover plate. Moreover, a bottom surface of each optical key is contacted with a top surface of the circuit board. The upper cover plate is an integral structure. Consequently, the components of the optical keyboard are simplified, and the assembling precision is enhanced.

### FIELD OF THE INVENTION

The present invention relates to an optical keyboard, and more particularly to an optical keyboard with a simplified assembled structure.

### BACKGROUND OF THE INVENTION

As known, keyboards are indispensable input devices for people in the modern societies. Generally, plural keys are installed on a top surface of the keyboard. Via the keyboard, the user can press the keys to input commands.

FIG. 1 is a schematic cross-sectional view illustrating the components of a conventional keyboard. As shown in FIG. 1, the conventional keyboard 7 comprises an upper cover plate 71, an intermediate metal plate 72, a circuit board 73, plural keys 74 and a bottom plate 75. Firstly, the plural keys 74 are positioned on the circuit board 73 with the assistance of the intermediate metal plate 72. Since a top surface of the upper cover plate 71 has an incline, the circuit board 73 is then assembled with the bottom plate 75 through a raised block 76. Consequently, after the upper cover plate 71 is assembled with the bottom plate 75, the keys 74 are penetrated through a hollow portion 710 of the upper cover plate 71. In addition, the heights of the keys 74 are determined according to incline of the upper cover plate 71.

However, the assembled structure of the conventional keyboard 7 still has some drawbacks. For example, the presence of the raised block 76 usually results in a floating tolerance of assembling the conventional keyboard 7. That is, the assembling precision is usually unsatisfied. Moreover, the foreign dust or liquid easily flies or permeates through the hollow portion 710 and stays on the top surface of the circuit board 73. Under this circumstance, the key is erroneously triggered to generate a signal, and the precision is deteriorated. Therefore, the conventional keyboard needs to be further improved

### SUMMARY OF THE INVENTION

The present invention provides an optical keyboard. In the optical keyboard, optical keys are directly installed on the upper cover plate. Moreover, the intermediate metal plate of the conventional keyboard is not used in the optical keyboard of the present invention. Consequently, the assembling precision is enhanced. Moreover, the optical keys are connected with the integral upper cover plate to collaboratively form a seal structure. Consequently, the waterproof and dustproof functions are achieved.

In accordance with an aspect of the present invention, there is provided an optical keyboard. The optical keyboard includes an upper cover plate, a bottom plate, a circuit board and plural optical keys. The upper cover plate includes at least one key regions and a periphery region. The periphery region is arranged around the at least one key region. The at least one key region and the periphery region are integrally formed with each other. The at least one key region includes plural openings. The bottom plate is connected with the periphery region of the upper cover plate. An accommodation space is defined by the upper cover plate and the bottom plate collaboratively. The circuit board is accommodated within the accommodation space, and connected with the upper cover plate. The plural optical keys penetrated through the corresponding openings of the at least one key region of the upper cover plate, and connected with the circuit board.

In an embodiment, the key region includes an inner ring sidewall and a position-limiting structure. The inner ring sidewall is protruded upwardly from the position-limiting structure and toward the periphery region of the upper cover plate, and connected with the periphery region, so that the position-limiting structure is at a level lower than the periphery region. The plural openings are formed in the position-limiting structure.

In an embodiment, the circuit board includes plural first fixing holes, and the upper cover plate includes plural first protrusion posts that are protruded from a bottom surface of the upper cover plate and toward the circuit board. The plural first protrusion posts of the upper cover plate are aligned and contacted with the corresponding first fixing holes of the circuit board. Moreover, screws are penetrated through the corresponding first fixing holes and tightened in the first protrusion posts.

In an embodiment, the circuit board further includes plural position-limiting holes, and the upper cover plate further includes plural second protrusion posts that are protruded from the bottom surface of the upper cover plate and toward the circuit board. After the second protrusion posts are penetrated through the corresponding position-limiting holes of the circuit board, the plural second protrusion posts are aligned and contacted with corresponding second fixing holes of a hub board. Moreover, screws are penetrated through the corresponding second fixing holes and tightened in the second protrusion posts. Preferably, the hub board is a USB hub board.

In an embodiment, a locking structure is protruded from an outer lateral surface of each optical key. The locking structure is locked on the position-limiting structure. The outer lateral surface of the optical key is tightly contacted with the position-limiting structure through the locking structure. The upper cover plate and the plural optical keys are collaboratively formed as a seal structure to shelter the circuit board, which is disposed under the upper cover plate.

In an embodiment, the locking structure includes an upper bulge, a lower bulge and a recess between the upper bulge and the lower bulge. A distance between a tip of the lower bulge and the outer lateral surface of the optical key is smaller than a distance between a tip of the upper bulge and the outer lateral surface of the optical key. After the lower bulge is penetrated downwardly through the position-limiting structure of the corresponding key region, the upper bulge is contacted with the position-limiting structure, and the position-limiting structure of the key region is clamped between the upper bulge and the lower bulge of the optical key and fixed in the recess.

In an embodiment, each of the plural optical keys further includes a positioning post, and the positioning post is protruded from a bottom surface of the optical key. The circuit board further includes plural positioning holes. The positioning post is penetrated through the corresponding positioning hole of the circuit board.

In an embodiment, the circuit board further includes plural light-emitting elements, and the plural light-emitting elements are disposed on a top surface of the circuit board and arranged beside the corresponding positioning holes. A light-inputting hole is formed in the bottom surface of each optical key. The bottom surface of the optical key is contacted with the top surface of the circuit board. Each of the plural light-emitting elements is received in the corresponding light-inputting hole of the optical key. A sensing light from the light-emitting element is introduced into the optical key so as to be detected.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic cross-sectional view illustrating the components of a conventional keyboard;

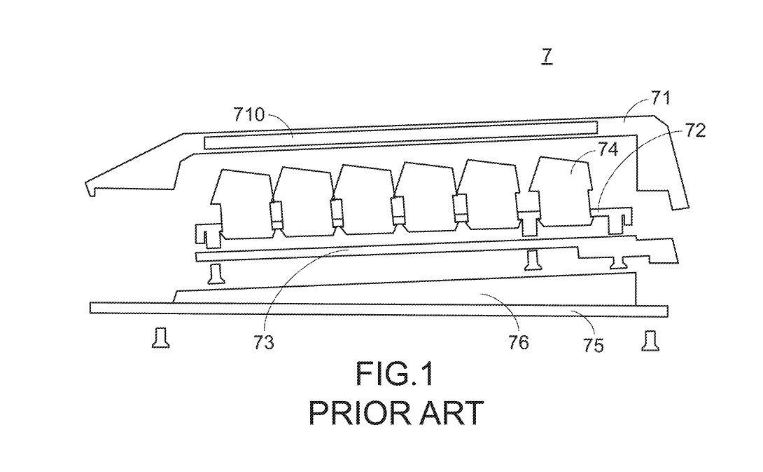

FIG. 2 is a schematic perspective view illustrating an optical keyboard according to an embodiment of the present invention;

FIG. 3 is a schematic perspective view illustrating the upper cover plate of the optical keyboard according to the embodiment of the present invention;

FIG. 4 is a schematic exploded view illustrating the optical keyboard according to the embodiment of the present invention;

FIG. 5 is a schematic exploded view illustrating the optical keyboard of FIG. 4 and taken along another viewpoint;

FIG. 6 is a schematic exploded view illustrating the relationship between an optical key and the optical keyboard according to the embodiment of the present invention;

FIG. 7 is a schematic cross-sectional view illustrating the optical keyboard according to the embodiment of the present invention, in which the optical key is not assembled with the upper cover plate and the circuit board; and

FIG. 8 is a schematic cross-sectional view illustrating the optical keyboard according to the embodiment of the present invention, in which the optical key is assembled with the upper cover plate and the circuit board.

### DETAILED DESCRIPTION OF THE PREFERRED EMBODIMENT

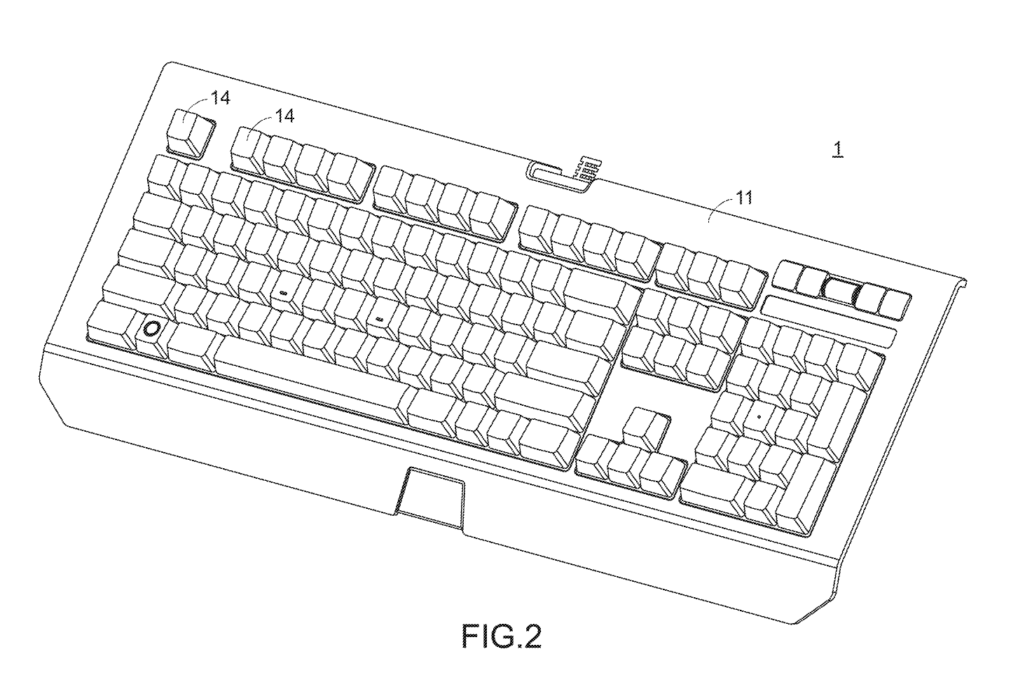

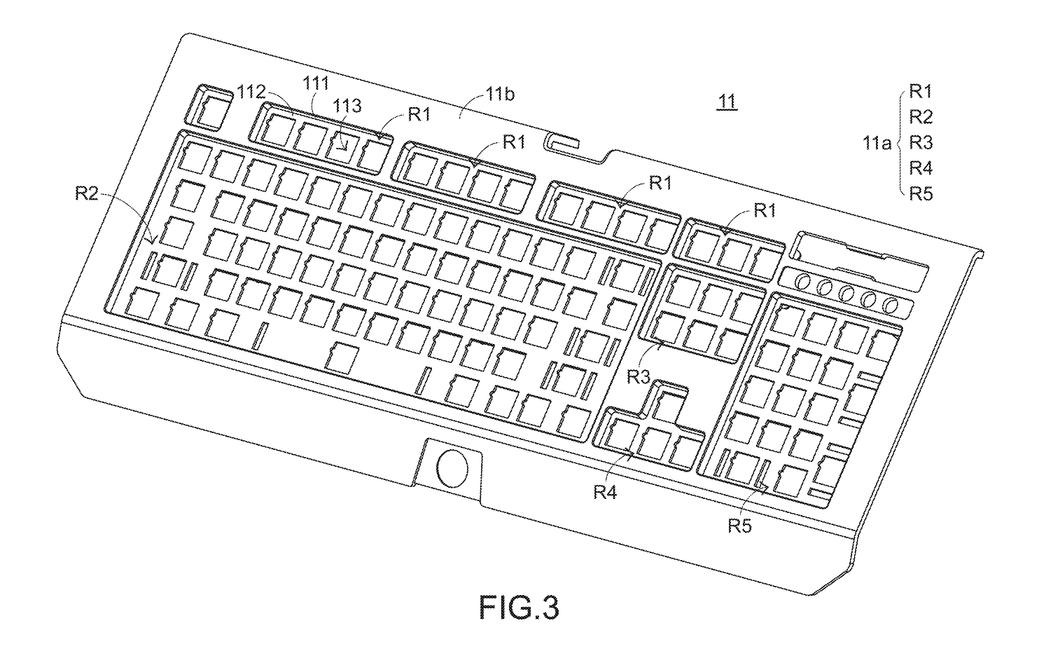

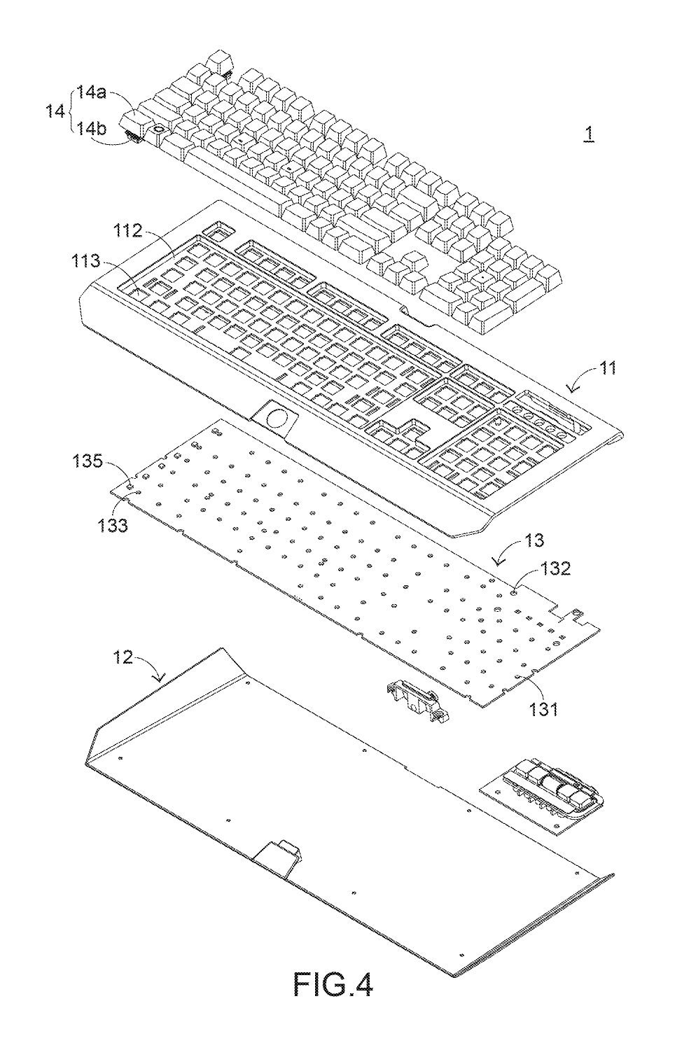

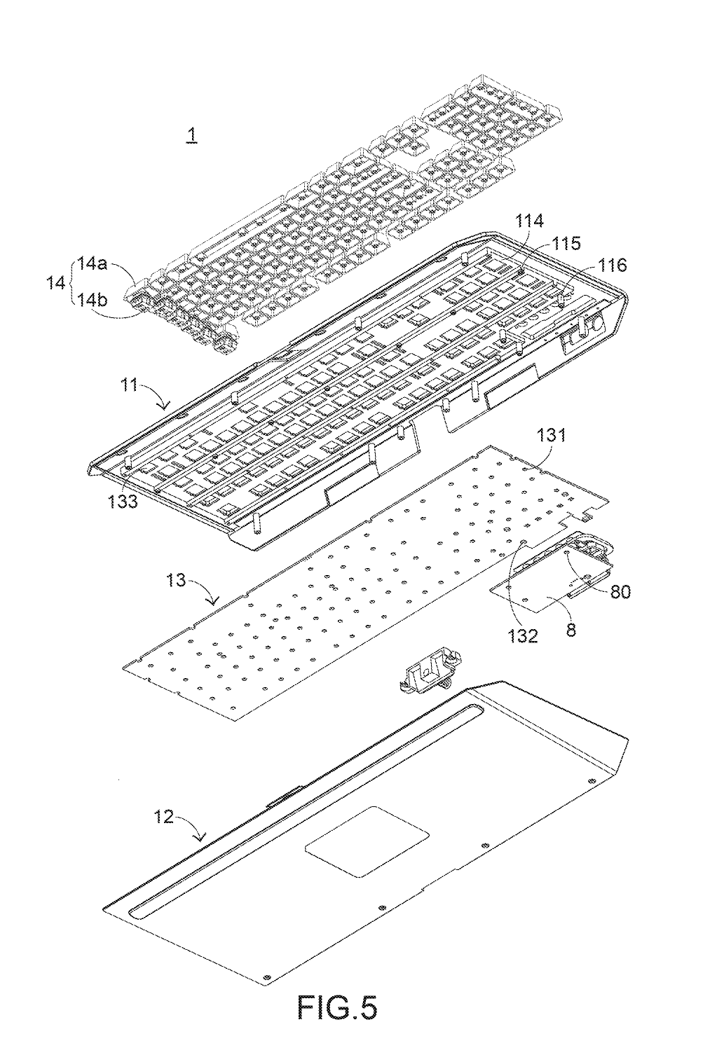

FIG. 2 is a schematic perspective view illustrating an optical keyboard according to an embodiment of the present invention. FIG. 3 is a schematic perspective view illustrating the upper cover plate of the optical keyboard according to the embodiment of the present invention. FIG. 4 is a schematic exploded view illustrating the optical keyboard according to the embodiment of the present invention. FIG. 5 is a schematic exploded view illustrating the optical keyboard of FIG. 4 and taken along another viewpoint.

The main components of the optical keyboard 1 will be described as follows. The optical keyboard 1 comprises an upper cover plate 11, a bottom plate 12, a circuit board 13 and plural optical keys 14. As shown in FIGS. 2 and 3, the upper cover plate 11 is an integral structure. Moreover, the upper cover plate 11 comprises at least one key region 11a and a periphery region 11b. The key region 11a comprises plural openings 113 for allowing the corresponding optical keys 14 to penetrate through.

Preferably, the upper cover plate 11 comprises plural key regions 11a. For example, these key regions 11a comprise an F1˜F12 key region R1, an alphabetic key region R2, a function key region R3, a direction key region R4 and a numeric key region R5. The periphery region 11b is arranged around these key regions R1˜R5. The outer appearance of the upper cover plate 11 is mainly defined by the periphery region 11b and the key regions R1˜R5 collaboratively. The positions of these key regions 11a are presented herein for purpose of illustration and description only.

As shown in FIG. 3, each key region 11a comprises an inner ring sidewall 111 and a position-limiting structure 112. The inner ring sidewall 111 and the position-limiting structure 112 are integrally formed with the periphery region 11b. The inner ring sidewall 111 is protruded upwardly from the position-limiting structure 112 and toward the periphery region 11b of the upper cover plate 11, and connected with the periphery region 11b. Consequently, the position-limiting structure 112 is at the level lower than the periphery region 11b. Moreover, the plural openings 113 are formed in the position-limiting structure 112.

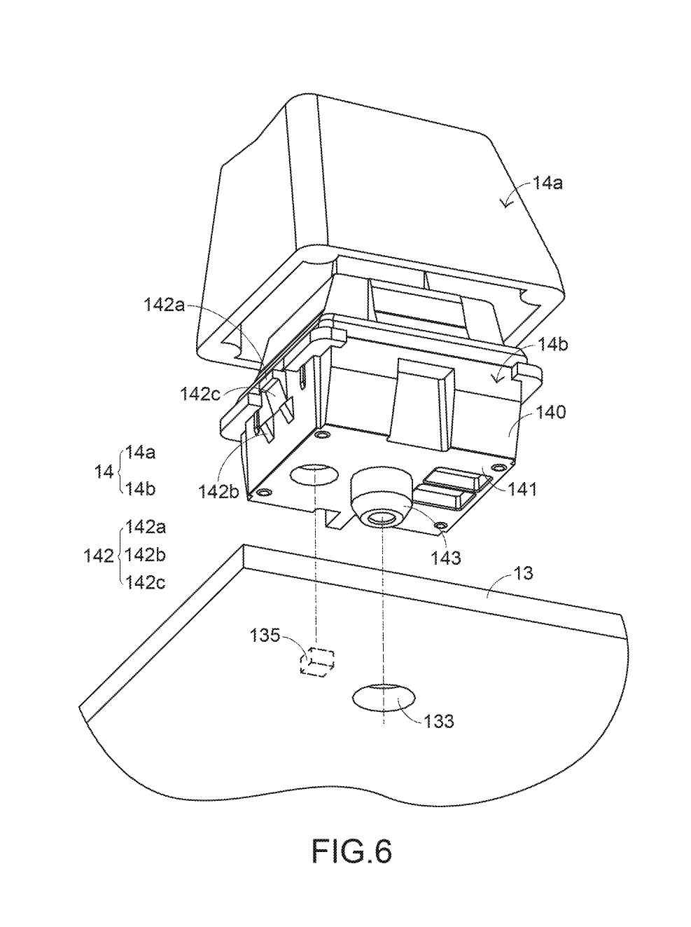

FIG. 6 is a schematic exploded view illustrating the relationship between an optical key and the optical keyboard according to the embodiment of the present invention. Please refer to FIGS. 4, 5 and 6. Each optical key 14 comprises a keycap 14a and a main body 14b. For succinctness and clarification, only the keycaps 14a and the main bodies 14b of the optical keys 14 in the leftmost row are completely shown in FIGS. 4 and 5. The main bodies of the other optical keys 14 are not shown. In fact, all of the optical keys 14 have respective main bodies.

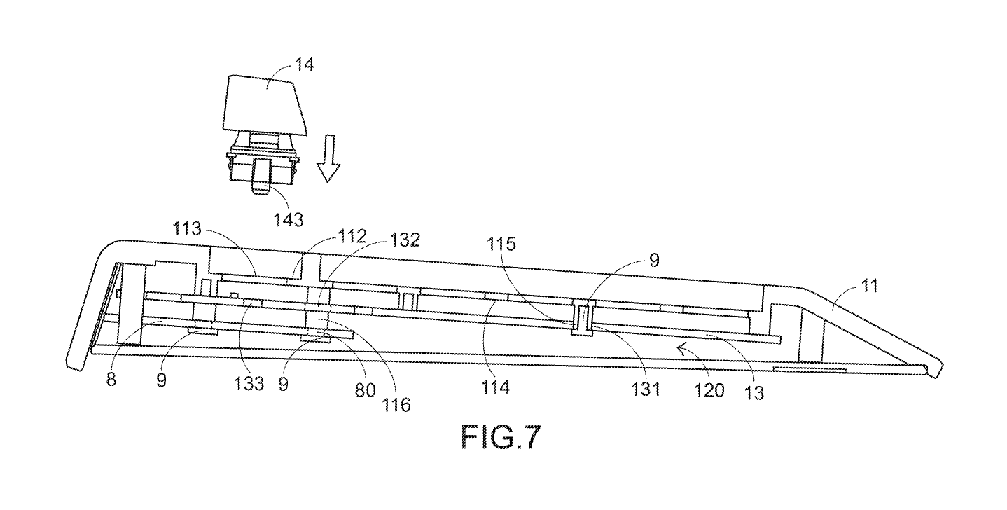

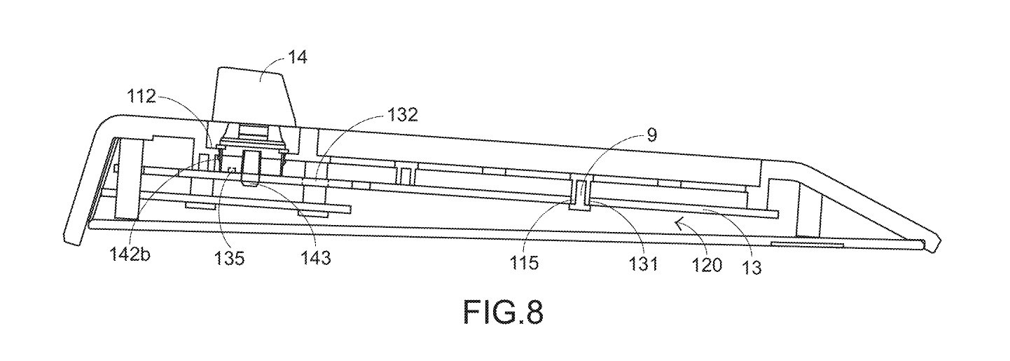

FIG. 7 is a schematic cross-sectional view illustrating the optical keyboard according to the embodiment of the present invention, in which the optical key is not assembled with the upper cover plate and the circuit board. FIG. 8 is a schematic cross-sectional view illustrating the optical keyboard according to the embodiment of the present invention, in which the optical key is assembled with the upper cover plate and the circuit board. Please refer to FIGS. 4, 5, 7 and 8. For succinctness, only one optical key is shown in FIGS. 7 and 8. When the upper cover plate 11 and the bottom plate 12 are combined together, the periphery region of the upper cover plate 11 and the corresponding edges of the bottom plate 12 are connected with each other. Meanwhile, an accommodation space 120 is defined by the upper cover plate 11 and the bottom plate 12 collaboratively, and the circuit board 13 is accommodated within the accommodation space 120. More especially, the circuit board 13 of the optical keyboard 1 is fixed by the upper cover plate 11. The connecting relationship between the upper cover plate 11 and the circuit board 13 is shown in FIG. 7. The circuit board 13 is contacted with the upper cover plate 11, and the circuit board 13 is fixed on the upper cover plate 11 through screws 9. Moreover, each optical key 14 is aligned with the corresponding opening 113 of the key region 11a of the upper cover plate 11. That is, the optical key 14 is penetrated through the corresponding opening 113, and connected with the circuit board 13.

The assembling structure between the upper cover plate 11 and the circuit board 13 will be described in more details as follows. In this embodiment, the circuit board 13 comprises plural first fixing holes 131, and the upper cover plate 11 comprises plural first protrusion posts 115. The plural first protrusion posts 115 are protruded from a bottom surface 114 of the upper cover plate 11, and the plural first protrusion posts 115 are protruded toward the circuit board 13. Moreover, the first protrusion posts 115 of the upper cover plate 11 are aligned and contacted with the corresponding first fixing holes 131 of the circuit board 13. The screws 9 are penetrated through the corresponding first fixing holes 131 and tightened in the first protrusion posts 115. In other words, the circuit board 13 is directly attached on the bottom surface 114 of the upper cover plate 11. In case that the upper cover plate 11 has an incline, the incline of the circuit board 13 is identical to the incline of the upper cover plate 11. Consequently, after the optical keys 14 are assembled with the upper cover plate 11 and the circuit board 13, the height distribution of the optical keys 14 matches the incline of the upper cover plate 11. In comparison with the conventional technologies, the intermediate metal plate and the raised block are not included in the optical keyboard 1 of the present invention. Consequently, the assembling precision of the optical keyboard 1 is largely enhanced.

In an embodiment, the circuit board 13 further comprises plural position-limiting holes 132, and the upper cover plate 11 further comprises plural second protrusion posts 116. The plural second protrusion posts 116 are protruded from the bottom surface 114 of the upper cover plate 11, and the plural second protrusion posts 116 are protruded toward the circuit board 13. After the second protrusion posts 116 are penetrated through the corresponding position-limiting holes 132 of the circuit board 13, the second protrusion posts 116 are aligned and contacted with corresponding second fixing holes 80 of a hub board 8. The screws 9 are penetrated through the corresponding second fixing holes 80 and tightened in the second protrusion posts 116. Preferably, the hub board 8 is a USB hub board.

The keys 14 of the optical keyboard 1 are optical keys. The uses of the optical keys 14 have many benefits in the process of assembling the optical keyboard 1. For example, it is not necessary to weld the optical keys. During the assembling process, the optical keys 14 are penetrated downwardly through the upper cover plate 11 and connected with the circuit board 13. Please refer to FIGS. 6 and 8. The optical key 14 further comprises a positioning post 143. The positioning post 143 is protruded from a bottom surface 141 of the optical key 14. The circuit board 13 further comprises plural positioning holes 133. The positioning posts 143 of the optical keys 14 are penetrated through the corresponding positioning holes 133 of the circuit board 13. Consequently, the optical keys 14 are fixed on the proper positions of the circuit board 13.

Please refer to FIGS. 3, 6 and 8 again. When the optical keys 14 are penetrated through the circuit board 13, the optical keys 14 are also locked on the upper cover plate 11. As shown in these drawings, a locking structure 142 is protruded from an outer lateral surface 140 of each optical key 14. The locking structure 142 is locked on the position-limiting structure 112. Through the locking structure 142, the outer lateral surface 140 of each optical key 14 is tightly contacted with the position-limiting structure 112. Consequently, the upper cover plate 11 and all of the optical keys 14 are collaboratively formed as a seal structure to shelter the circuit board 13, which is disposed under the upper cover plate 11. Consequently, the seal structure can prevent the foreign matters at the top side from entering the accommodation space. Under this circumstance, the circuit board 13 is not interfered by the foreign matters, and the waterproof and dustproof functions are achieved.

In this embodiment, the locking structure 142 comprises an upper bulge 142a, a lower bulge 142b and a recess 142c. The recess 142c is arranged between the upper bulge 142a and the lower bulge 142b. The distance between the tip of the lower bulge 142b and the outer lateral surface 140 of the optical key 14 is smaller than the distance between the tip of the upper bulge 142a and the outer lateral surface 140 of the optical key 14. Moreover, the lower bulge 142b has a slant surface. Due to the slant surface, the lower bulge 142b can be penetrated downwardly through the position-limiting structure 112 of the key region 11a more smoothly. After the lower bulge 142b is penetrated through the position-limiting structure 112, the upper bulge 142a is contacted with the position-limiting structure 112. Since the position-limiting structure 112 of the key region 11a is clamped between the upper bulge 142a and the lower bulge 142b of the optical key 14 and fixed in the recess 142c, the optical key 14 is positioned in the key region 11a.

In this embodiment, the circuit board 13 further comprises plural light-emitting elements 135. The plural light-emitting elements 135 are disposed on a top surface of the circuit board 13. Moreover, the plural light-emitting elements 135 are arranged beside the corresponding positioning holes 133. Moreover, a light-inputting hole is formed in the bottom surface 141 of the optical key 14. The bottom surface 141 of the optical key 14 is contacted with the top surface of the circuit board 13. The light-emitting element 135 is received in the light-inputting hole of the corresponding optical key 14. Consequently, a sensing light from the light-emitting element 135 can be introduced into the optical key 14 so as to be detected. Moreover, a light receiver (not shown) is disposed within the optical region 14. Due to the cooperation of the light-emitting element 135 and the light receiver, the optical key 14 can detect the sensing light and generate a triggering signal. For succinctness and clarification, only the light-emitting elements 135 in the leftmost row are completely shown in FIG. 4. In fact, the number of the light-emitting elements 135 is equal to the number of the optical keys 14.

From the above descriptions, the present invention provides the optical keyboard. The circuit board is directly combined with the upper cover plate. Consequently, the components of the optical keyboard are simplified, and the assembling precision is enhanced. Moreover, since the upper cover plate is an integral structure and the optical keys are firmly locked on the upper cover plate, the waterproof and dustproof functions are achieved.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. An optical keyboard, comprising:
an upper cover plate comprising at least one key regions and a periphery region, wherein the periphery region is arranged around the at least one key region, and the at least one key region and the periphery region are integrally formed with each other, wherein the at least one key region comprises plural openings;
a bottom plate connected with the periphery region of the upper cover plate, wherein an accommodation space is defined by the upper cover plate and the bottom plate collaboratively;
a circuit board accommodated within the accommodation space, and connected with the upper cover plate; and
plural optical keys penetrated through the corresponding openings of the at least one key region of the upper cover plate, and connected with the circuit board.

2. The optical keyboard according to claim 1, wherein the key region comprises an inner ring sidewall and a position-limiting structure, wherein the inner ring sidewall is protruded upwardly from the position-limiting structure and toward the periphery region of the upper cover plate, and connected with the periphery region, so that the position-limiting structure is at a level lower than the periphery region, wherein the plural openings are formed in the position-limiting structure.

3. The optical keyboard according to claim 2, wherein the circuit board comprises plural first fixing holes, and the upper cover plate comprises plural first protrusion posts that are protruded from a bottom surface of the upper cover plate and toward the circuit board, wherein the plural first protrusion posts of the upper cover plate are aligned and contacted with the corresponding first fixing holes of the circuit board, and screws are penetrated through the corresponding first fixing holes and tightened in the first protrusion posts.

4. The optical keyboard according to claim 3, wherein the circuit board further comprises plural position-limiting holes, and the upper cover plate further comprises plural second protrusion posts that are protruded from the bottom surface of the upper cover plate and toward the circuit board, wherein after the second protrusion posts are penetrated through the corresponding position-limiting holes of the circuit board, the plural second protrusion posts are aligned and contacted with corresponding second fixing holes of a hub board, and screws are penetrated through the corresponding second fixing holes and tightened in the second protrusion posts, wherein the hub board is a USB hub board.

5. The optical keyboard according to claim 2, wherein a locking structure is protruded from an outer lateral surface of each optical key, the locking structure is locked on the position-limiting structure, and the outer lateral surface of the optical key is tightly contacted with the position-limiting structure through the locking structure, wherein the upper cover plate and the plural optical keys are collaboratively formed as a seal structure to shelter the circuit board which is disposed under the upper cover plate.

6. The optical keyboard according to claim 5, wherein the locking structure comprises an upper bulge, a lower bulge and a recess between the upper bulge and the lower bulge, wherein a distance between a tip of the lower bulge and the outer lateral surface of the optical key is smaller than a distance between a tip of the upper bulge and the outer lateral surface of the optical key, wherein after the lower bulge is penetrated downwardly through the position-limiting structure of the corresponding key region, the upper bulge is contacted with the position-limiting structure, and the position-limiting structure of the key region is clamped between the upper bulge and the lower bulge of the optical key and fixed in the recess.

7. The optical keyboard according to claim 6, wherein each of the plural optical keys further comprises a positioning post, and the positioning post is protruded from a bottom surface of the optical key, wherein the circuit board further comprises plural positioning holes, and the positioning post is penetrated through the corresponding positioning hole of the circuit board.

8. The optical keyboard according to claim 7, wherein the circuit board further comprises plural light-emitting elements, and the plural light-emitting elements are disposed on a top surface of the circuit board and arranged beside the corresponding positioning holes, wherein a light-inputting hole is formed in the bottom surface of each optical key, the bottom surface of the optical key is contacted with the top surface of the circuit board, each of the plural light-emitting elements is received in the corresponding light-inputting hole of the optical key, and a sensing light from the light-emitting element is introduced into the optical key so as to be detected.
